(19) United States
(12) Patent Application Publication
(10) Pub. No.: US 2024/0292626 A1
(43) Pub. Date: Aug. 29, 2024

(54) SEMICONDUCTOR MEMORY DEVICE AND METHOD OF MANUFACTURING THE SAME

(71) Applicant: Kioxia Corporation, Tokyo (JP)

(72) Inventors: Kazuki SHOJI, Yokkaichi Mie (JP); Tadashi IGUCHI, Yokkaichi Mie (JP)

(73) Assignee: Kioxia Corporation, Tokyo (JP)

(21) Appl. No.: 18/585,206

(22) Filed: Feb. 23, 2024

(30) Foreign Application Priority Data
Feb. 24, 2023 (JP) 2023-027212

(51) Int. Cl. H10B 43/35; H10B 43/10; H10B 43/20

(52) U.S. Cl. CPC H10B 43/35; H10B 43/10; H10B 43/20

(57) ABSTRACT

A semiconductor memory device includes a first stacked body that includes first insulating films and first conductive films alternately stacked in a first direction; first columnar bodies each including a first semiconductor structure extending through the first stacked body, the plurality of first columnar bodies being configured as memory cells; and a plurality of second columnar bodies that each include at least one conductor extending through the first stacked body in the first direction, and are each coupled to a corresponding one of the first conductive films and a stacked film including second, third, and fourth insulating films, wherein the second to fourth insulating films are provided between the at least one conductor and the first stacked body.

### CROSS-REFERENCE TO RELATED APPLICATION

This application is based upon and claims the benefit of priority from Japanese Patent Application No. 2023-027212, filed Feb. 24, 2023, the entire contents of which are incorporated herein by reference.

### FIELD

Embodiments described herein relate generally to a semiconductor memory device and a method of manufacturing the same.

### BACKGROUND

A semiconductor memory device such as a NAND flash memory may include a three-dimensional memory cell array in which a plurality of memory cells are disposed three-dimensionally. In such a three-dimensional memory cell array, a plurality of word lines are formed by a plurality of stacked conductive layers. The plurality of conductive layers are electrically connected to each of a plurality of word line contacts extending in a stacking direction. The word line contacts are formed up to the corresponding word lines, and thus have different depths. When contact holes of the word line contacts having different depths are formed, an over-etching time for the conductive layer varies depending on the contact hole. In this case, there is a concern that the contact hole may penetrate the conductive layer, and the word line contact cannot be connected to an intended word line.

### DESCRIPTION OF THE DRAWINGS

FIG. 1 is a diagram showing a configuration example of a semiconductor memory device according to a first embodiment.

FIG. 2 is a diagram showing an example of a circuit configuration of a memory cell array 10 provided in the semiconductor memory device according to the first embodiment.

FIG. 3 is a cross-sectional view showing a detailed configuration example of the semiconductor memory device. FIG. 4 is a schematic cross-sectional view showing a configuration example of a memory cell.

FIG. 5 is a schematic cross-sectional view showing a configuration example of the memory cell.

FIG. 6 is a cross-sectional view showing configuration examples of word line contacts and support portions.

FIG. 7 is a plan view showing configuration examples of the word line contact and the support portion.

FIG. 8 is a cross-sectional view showing an example of a method of manufacturing the semiconductor memory device according to the first embodiment.

FIG. 9 is a cross-sectional view subsequent to FIG. 8 and showing an example of a method of manufacturing the semiconductor memory device.

FIG. 10 is a cross-sectional view subsequent to FIG. 9 and showing an example of a method of manufacturing the semiconductor memory device.

FIG. 11 is a cross-sectional view subsequent to FIG. 10 and showing an example of a method of manufacturing the semiconductor memory device.

FIG. 12 is a cross-sectional view subsequent to FIG. 11 and showing an example of a method of manufacturing the semiconductor memory device.

FIG. 13 is a cross-sectional view subsequent to FIG. 12 and showing an example of a method of manufacturing the semiconductor memory device.

FIG. 14 is a cross-sectional view subsequent to FIG. 13 and showing an example of a method of manufacturing the semiconductor memory device.

FIG. 15 is a cross-sectional view subsequent to FIG. 14 and showing an example of a method of manufacturing the semiconductor memory device.

FIG. 16 is a cross-sectional view subsequent to FIG. 15 and showing an example of a method of manufacturing the semiconductor memory device.

FIG. 17 is a cross-sectional view subsequent to FIG. 16 and showing an example of a method of manufacturing the semiconductor memory device.

FIG. 18 is a cross-sectional view subsequent to FIG. 17 and showing an example of a method of manufacturing the semiconductor memory device.

FIG. 19 is a cross-sectional view subsequent to FIG. 18 and showing an example of a method of manufacturing the semiconductor memory device.

FIG. 20 is a cross-sectional view subsequent to FIG. 19 and showing an example of a method of manufacturing the semiconductor memory device.

### DETAILED DESCRIPTION

Embodiments provide a semiconductor memory device in which contacts can be reliably connected to intended word lines, and a method of manufacturing the same.

In general, according to one embodiment, a semiconductor memory device includes a first stacked body that includes a plurality of first insulating films and a plurality of first conductive films alternately stacked in a first direction; a plurality of first columnar bodies that each include a first semiconductor structure extending through the first stacked body in the first direction, and a first insulator structure provided between the first semiconductor structure and the first stacked body, the plurality of first columnar bodies being configured such that memory cells are provided to correspond to intersections between the first columnar bodies and the first stacked body; and a plurality of second columnar bodies that each include at least one conductor extending through the first stacked body in the first direction, and are each coupled to a corresponding one of the first conductive films and a stacked film including second, third, and fourth insulating films, wherein the second to fourth insulating films are provided between the at least one conductor and the first stacked body.

An embodiment of the present disclosure will be described below with reference to the drawings. This embodiment does not limit the present disclosure. The drawings may be schematic or conceptual. In the specification and drawings, the same components are given the same reference numerals and signs.

### First Embodiment

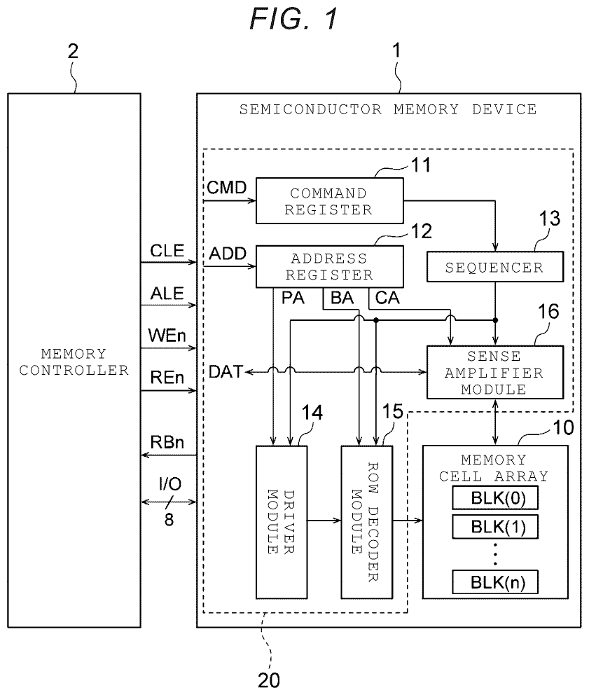

FIG. 1 is a diagram showing a configuration example of a semiconductor memory device 1 according to a first embodiment. The semiconductor memory device 1 is a NAND flash memory that can store data in a non-volatile manner. The semiconductor memory device 1 is controlled by an external memory controller 2. Communication between the semiconductor memory device 1 and the memory controller 2 is based on, for example, the NAND interface standard.

The semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK(0) to BLK(n) (n is an integer of 1 or more). The block BLK is a set of a plurality of memory cells that can store data in a non-volatile manner, and is used, for example, as a data erasure unit. Furthermore, the memory cell array 10 is provided with a plurality of bit lines and a plurality of word lines. Each memory cell is associated with, for example, one bit line and one word line. A detailed configuration of the memory cell array 10 will be described later.

The command register 11 stores a command CMD received from the memory controller 2 by the semiconductor memory device 1. The command CMD includes, for example, instructions for causing the sequencer 13 to execute a read operation, a write operation, an erase operation, and the like.

The address register 12 stores address information ADD received from the memory controller 2 by the semiconductor memory device 1. The address information ADD includes, for example, a block address BA, a page address PA, and a column address CA. For example, the block address BA, the page address PA, and the column address CA are used to select a block BLK, a word line, and a bit line, respectively.

The sequencer 13 controls the overall operation of the semiconductor memory device 1. For example, the sequencer 13 controls the driver module 14, the row decoder module 15, the sense amplifier module 16, and the like based on the command CMD stored in the command register 11 to execute a read operation, a write operation, an erase operation, and the like.

The driver module 14 generates voltages used in a read operation, a write operation, an erase operation, and the like. Then, the driver module 14 applies the generated voltage to a signal line corresponding to a selected word line, for example, based on the page address PA stored in the address register 12.

The row decoder module 15 includes a plurality of row decoders. The row decoder selects one block BLK in the corresponding memory cell array 10 based on the block address BA stored in the address register 12. Then, the row decoder transfers, for example, a voltage applied to the signal line corresponding to the selected word line to the selected word line in the selected block BLK.

In the write operation, the sense amplifier module 16 applies a desired voltage to each bit line according to write data DAT received from the memory controller 2. Furthermore, in the read operation, the sense amplifier module 16 determines data stored in the memory cell based on the voltage of the bit line, and transfers a determination result to the memory controller 2 as read data DAT.

The semiconductor memory device 1 and the memory controller 2 described above may be combined to constitute one semiconductor device. Examples of such a semiconductor device include a memory card such as an SDTM card, a solid state drive (SSD), and the like.

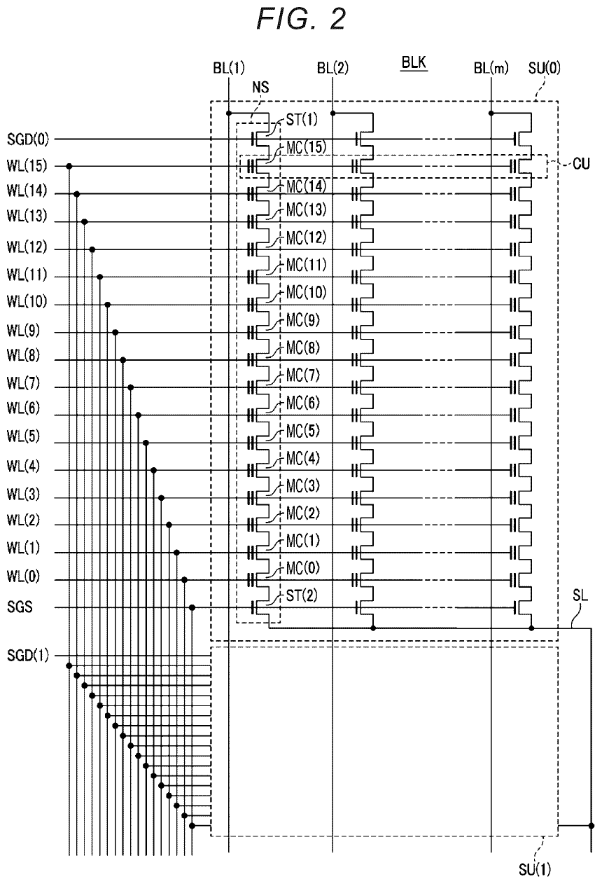

FIG. 2 is a diagram showing an example of a circuit configuration of the memory cell array 10 provided in the semiconductor memory device 1 according to the first embodiment. One block BLK among the plurality of blocks BLK included in the memory cell array 10 is shown in FIG. 2. As shown in FIG. 2, the block BLK includes a plurality of string units SU(0) to SU(k) (k is an integer of 1 or more).

Each string unit SU includes a plurality of NAND strings NS respectively associated with bit lines BL(0) to BL(m) (m is an integer of 1 or more). Each NAND string NS includes, for example, memory cells MC(0) to MC(15) and select transistors ST(1) and ST(2). The memory cell MC includes a control gate and a charge storage layer, and stores data in a non-volatile manner. Each of select transistors ST(1) and ST(2) is used to select a string unit SU during various operations.

In each NAND string NS, the memory cells MC(0) to MC(15) are connected in series. A drain of the select transistor ST(1) is connected to the associated bit line BL, and a source of the select transistor ST(1) is connected to one ends of the memory cells MC(0) to MC(15) connected in series. A drain of select transistor ST(2) is connected to the other ends of the memory cells MC(0) to MC(15) connected in series. A source of the select transistor ST(2) is connected to the source line SL.

In the same block BLK, the control gates of the memory cells MC(0) to MC(15) are connected in common to the word lines WL(0) to WL(15), respectively. Gates of the select transistors ST(1) in the string units SU(0) to SU(k) are connected in common to select gate lines SGD(0) to SGD(k), respectively. Gates of the select transistors ST(2) are connected in common to a select gate line SGS.

In the circuit configuration of the memory cell array 10 described above, the bit line BL is shared by the NAND strings NS to which the same column address is assigned in each string unit SU. The source line SL is shared among the plurality of blocks BLK, for example.

A set of the plurality of memory cells MC connected to a common word line WL in one string unit SU is referred to as, for example, a cell unit CU. For example, the storage capacity of the cell unit CU including the memory cells MC each storing 1-bit data is defined as “1-page data.” The cell unit CU may have a storage capacity of 2-page data or more depending on the number of bits of data stored in the memory cells MC.

The memory cell array 10 provided in the semiconductor memory device 1 according to the first embodiment is not limited to the circuit configuration described above. For example, the number of memory cells MC and the number of select transistors ST(1) and ST(2) provided in each NAND string NS may be designed to be any number. The number of string units SU provided in each block BLK may be designed to be any number.

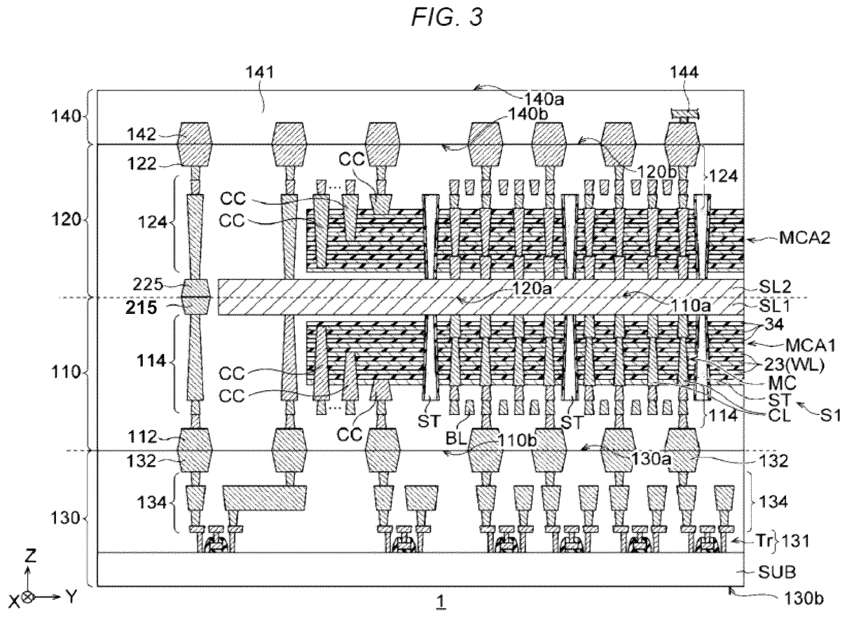

FIG. 3 is a cross-sectional view showing a detailed configuration example of the semiconductor memory device 1. The semiconductor memory device 1 includes memory cell array layers 110 and 120 and a control circuit layer 130.

The memory cell array layer 110 and the memory cell array layer 120 are bonded together on a first surface 110a and a third surface 120a. Source layers SL1 and SL2 are bonded together on a bonding surface between the memory cell array layer 110 and the memory cell array layer 120. Thereby, the source layers SL1 and SL2 function as integrated common source layer SL1 and SL2. Memory cell arrays MCA1 and MCA2 are electrically connected to the common source layers SL1 and SL2. As an example of the memory cell array 10, three-dimensional memory cell arrays MCA1 and MCA2 in which the memory cells MC are three-dimensionally arranged are shown.

On the bonding surface between the memory cell array layer 110 and the memory cell array layer 120, a pad 215 of the memory cell array layer 110 and a pad 225 of the memory cell array layer 120 are bonded together. The pad 225 is electrically connected to any semiconductor element such as a transistor Tr of the control circuit layer 130 via a multilayer wiring layer 114 of the memory cell array layer 110, the pad 112, and the like.

The memory cell array layer 110 and the control circuit layer 130 are bonded together on a second surface 110b and a fifth surface 130a. The pad 112 of the memory cell array layer 110 and a pad 132 of the control circuit layer 130 are bonded together on a bonding surface between the memory cell array layer 110 and the control circuit layer 130. The pad 132 is electrically connected to a semiconductor element such as the transistor Tr of the control circuit layer 130 via a multilayer wiring layer 134.

The memory cell array layer 120 and the multilayer wiring layer 140 are bonded together on a fourth surface 120b and an eighth surface 140b. A pad 122 of the memory cell array layer 120 and a pad 142 of the multilayer wiring layer 140 are bonded together on a bonding surface between the memory cell array layer 120 and the multilayer wiring layer 140. The pad 142 is electrically connected to a wiring 144 and electrically bonded to a memory cell array MCA2 via the pad 122 of the memory cell array layer 120 and the multilayer wiring layer 124.

In this manner, a memory cell array MCA1 of the memory cell array layer 110 is electrically connected to a CMOS circuit 131 of the control circuit layer 130 via the multilayer wiring layers 114 and 134 and the pads 112 and 132. The memory cell array MCA2 of the memory cell array layer 120 is electrically connected to the CMOS circuit 131 of the control circuit layer 130 via the multilayer wiring layers 140, 114, 124, and 134 and the pads 112, 122, 132, and 142.

Thereby, the control circuit layer 130 is shared by the memory cell array layers 110 and 120, and can control both the memory cell arrays MCA1 and MCA2. Further, the source layers SL1 and SL2 are also electrically connected to the CMOS circuit 131 via the multilayer wiring layer 114 and the like, and may be further connected to an external power source, which is not shown in the drawing, via the multilayer wiring layers 114, 124, 134, and 140. Thereby, a source voltage from the outside can be transmitted to the source layers SL1 and SL2.

The memory cell arrays MCA1 and MCA2 may have basically the same configuration. Thus, only the configuration of the memory cell array MCA1 will be described below.

The memory cell array MCA1 includes a stacked body S1. The stacked body S1 is configured by alternately stacking a plurality of electrode films 23 and a plurality of insulating films 34 in a Z direction. The stacked body S1 constitutes a memory cell array. For the electrode film 23, a conductive film such as tungsten is used. For the insulating film 34, an insulating film such as a silicon oxide film is used. The insulating film 34 insulates the electrode films 23 from each other. That is, the plurality of electrode films 23 are stacked in a mutually insulated state. The number of stacked layers of each of the electrode film 23 and the insulating film 34 is freely selected. The insulating film 34 may be, for example, a porous insulating film or an air gap.

One or a plurality of electrode films 23 at an upper end and a lower end of the stacked body S1 in the Z direction function as the select transistors ST(1) and ST(2), respectively. The electrode films 23 between the select transistors ST(1) and ST(2) function as the word lines WL. The word line WL is a gate electrode of memory cell MC. As shown in FIG. 2, the gate of the select transistor ST(1) on the drain side is connected to a drain-side select gate line SGD. The select transistor ST(1) is provided on the bit line BL side of the stacked body S1. The gate of the select transistor ST(2) on the source side is connected to a source-side select gate line SGS. The select transistor ST(2) is provided on the source layer SL1 side of the stacked body S1.

The memory cell array MCA1 includes a plurality of memory cells MC connected in series between the select transistor ST(1) and the select transistor ST(2). The select transistor ST(1), the select transistor ST(2), and the memory cell MC are connected in series to constitute a NAND string. The memory string is connected to the bit line BL via the multilayer wiring layer 114, for example. The bit line BL is a wiring provided below the stacked body S1 and extending in an X direction.

A plurality of columnar bodies CL are provided in the stacked body S1. The columnar bodies CL extend in the stacked body S1 in the stacking direction (Z direction) of the stacked body S1 so as to penetrate the stacked body S1, and are provided from the multilayer wiring layer 114 connected to the bit line BL to the source layer SL1. The memory cell MC is provided at an intersection between the columnar body CL and the electrode film 23. The internal structure of the columnar body CL will be described later. In this embodiment, the columnar bodies CL have a high aspect ratio, and thus the columnar bodies CL are formed to be divided into two stages in the Z direction. There is no problem even when the columnar bodies CL are formed in one stage or three or more stages.

Furthermore, a plurality of slits ST are provided in the stacked body S1. The slits ST extend in the X direction and penetrate the stacked body S1 in the stacking direction (Z direction) of the stacked body S1. The slit ST is filled with an insulating film such as a silicon oxide film, and the insulating film has a plate shape. The slit ST electrically isolates the electrode films 23 of the stacked body S1 from each other. Further, the slit ST may be a wiring having an insulating film provided on a side wall and a conductive film provided inside the insulating film. The conductive film in the slit ST is electrically insulated from the electrode film 23. Thereby, the slit ST can function as a source wiring electrically connected to the source layers SL1 and SL2 while electrically isolating the electrode films 23 of the stacked body S1 from each other.

A source layer SL1 is provided on the stacked body S1. For example, a low resistance metal material such as doped polysilicon, copper, aluminum, or tungsten is used for the source layer SL1.

A plurality of word line contacts CC extend in the Z direction in the stacked body S1 at an end of the memory cell array MCA1. The word line contacts CC are provided to correspond to the plurality of electrode films 23. The word line contacts CC extend to the corresponding electrode films 23 and are electrically connected to the electrode films 23. The word line contacts CC can also be provided at the center of the memory cell array MCA, or the like other than at the end thereof. The configuration of the word line contact CC will be described later in detail.

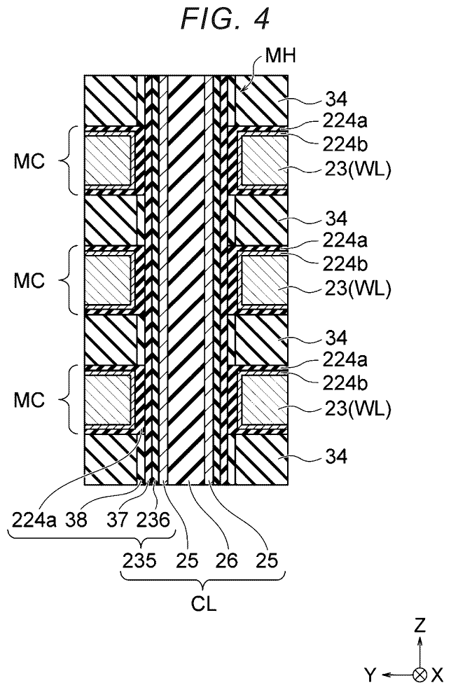

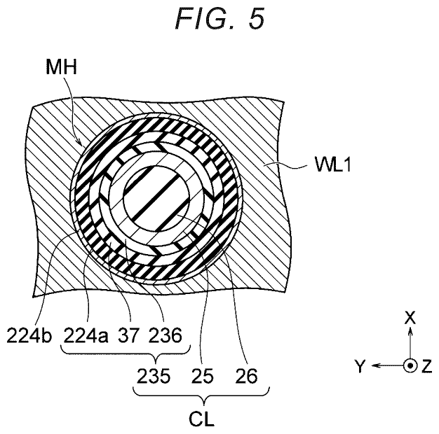

FIGS. 4 and 5 are schematic cross-sectional views showing a configuration example of the memory cell MC. The columnar bodies CL have the same configuration in the memory cell arrays MCA1 and MCA2.

As shown in FIG. 4, the columnar bodies CL are provided in memory holes MH provided in the electrode films 23 (hereinafter also referred to as word lines WL) which are stacked in the memory cell array MCA1. The columnar bodies CL penetrate the stacked body of the word lines WL from the upper end to the lower end of the stacked body in the Z direction. The columnar body CL includes a semiconductor body 25, a memory film 235, and a core layer 26. The columnar body CL includes the core layer 26 provided at the central part of the columnar body CL, the semiconductor body (semiconductor structure) 25 provided around the core layer 26, and the memory film (charge storage structure) 235 provided around the semiconductor body 25. The semiconductor body 25 extends in the stacking direction (Z direction) in the stacked body of the word lines WL. One end of the semiconductor body 25 is electrically connected to the source layer SL1. The other end of the semiconductor body 25 is electrically connected to the bit line BL. The memory film 235 is provided between the semiconductor body 25 and the word line WL and has a charge trapping portion.

As shown in FIG. 5, the shape of the memory hole MH in the XY plane is, for example, a circle or an ellipse. A block insulating film 224a constituting a portion of the memory film 235 may be provided between the word line WL and the insulating film 34. The block insulating film 224a is, for example, a silicon oxide film or a metal oxide film. One example of a metal oxide is aluminum oxide. As shown in FIG. 4, the block insulating film 224a and a barrier film 224b may be provided between the word line WL and the insulating film 34 and between the word line WL and the memory film 235. When the word line WL is made of tungsten, the barrier film 224b may be a stacked structure film of titanium nitride (TiN) and titanium (Ti), for example. The block insulating film 224a curbs back tunneling of charges from the word line WL to the memory film 235 side. The barrier film 224b improves adhesion between the word line WL and the block insulating film 224a.

The shape of the semiconductor body 25 is, for example, a cylindrical shape. For the semiconductor body 25, a semiconductor material such as polysilicon is used. The semiconductor body 25 is, for example, undoped silicon. The semiconductor body 25 may also be p-type silicon. The semiconductor body 25 functions as a channel for each memory cell MC.

In the memory film 235, a portion other than the block insulating film 224a is provided between the inner wall of the memory hole MH and the semiconductor body 25. The shape of the memory film 235 is, for example, a cylindrical shape. The plurality of memory cells MC have a storage region between the semiconductor body 25 and the word line WL, and are stacked in the Z direction. The memory film 235 includes, for example, a cover insulating film 38, a charge trapping film 37, and a tunnel insulating film 236 shown in FIG. 4. The semiconductor body 25, the charge trapping film 37, and the tunnel insulating film 236 each extend in the Z direction.

The cover insulating film 38 is provided between the insulating film 34 and the charge trapping film 37. The cover insulating film 38 contains, for example, silicon oxide. The cover insulating film 38 protects the charge trapping film 37 from being etched when a sacrificial film (not shown) is replaced with the word line WL (replacement process). The cover insulating film 38 may be removed from between the word line WL and the memory film 235 in the replacement process. In this case, for example, the block insulating film 224a is not provided between the word line WL and the charge trapping film 37. Furthermore, when the replacement process is not used to form the word line WL, the cover insulating film 38 may not be provided.

The charge trapping film 37 is provided between the block insulating film 224a, the cover insulating film 38, and the tunnel insulating film 236. The charge trapping film 37 contains, for example, silicon nitride (SiN), and has trap sites for trapping charges in the film. A portion of the charge trapping film 37 which is sandwiched between the word line WL and the semiconductor body 25 constitutes a storage region of the memory cell MC as a charge trapping portion. A threshold voltage of the memory cell MC changes depending on whether charges are included in the charge trapping portion or the amount of charges trapped in the charge trapping portion. Thereby, the memory cell MC stores information.

The tunnel insulating film 236 is provided between the semiconductor body 25 and the charge trapping film 37. The tunnel insulating film 236 contains, for example, silicon oxide or silicon oxide and silicon nitride. The tunnel insulating film 236 is a potential barrier between the semiconductor body 25 and the charge trapping film 37. For example, when electrons are injected into the charge trapping portion from the semiconductor body 25 (write operation) and when holes injected into the charge trapping portion from the semiconductor body 25 (erase operation), the electrons and the holes pass through (tunneling) a potential barrier of the tunnel insulating film 236.

The core layer 26 fills the interior space of the cylindrical semiconductor body 25. The shape of the core layer 26 is, for example, a columnar shape. The core layer 26 contains, for example, silicon oxide, and has an insulation property.

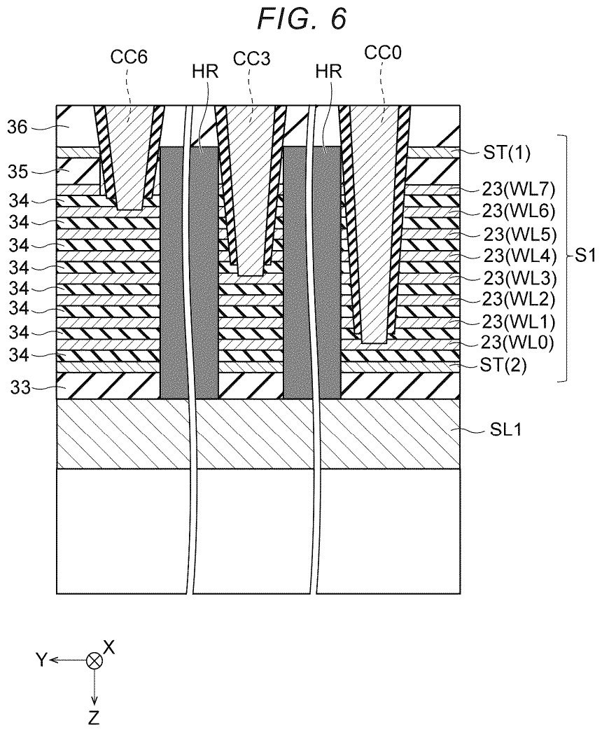

FIG. 6 is a cross-sectional view showing configuration examples of word line contacts CC and support portions HR. FIG. 6 shows the stacked body S1 upside down with respect to FIG. 3. Further, the stacked body of the memory cell array MCA2 also has the same configuration as that of the stacked body S1.

Word line contacts CC0 to CC7 and the support portions HR are provided at any positions on the stacked body S1. No columnar body CL is provided in a region where the word line contacts CC0 to CC7 are provided. That is, the word line contacts CC0 to CC7 are provided in an any region of the stacked body S1 where the memory cell array MCA1 is not provided. The word line contacts CC0 to CC7 may be provided at the ends of the memory cell array MCA1, or may be provided at a central portion or the like other than the ends.

In FIG. 6, only the word line contacts CC0, CC3, and CC6 are shown for convenience. Further, the number of word lines WL and the number of word line contacts CC are not limited, and may be 16 as shown in FIG. 2, or may be more or less than 16.

The word line contacts CC0 to CC7 each extend in the Z direction in the stacked body S1 and correspond to word lines WL0 to WL7, respectively. The word line contacts CC0 to CC7 extend to the depths of the respective word lines WL0 TO WL7, and are electrically connected to the corresponding word lines WL0 TO WL7. That is, the depths of conductors 44 of the word line contacts CC0 to CC7 are the positions of the corresponding word lines WL0 to WL7, respectively. The depths of the stacked films 40 of the word line contacts CC0 to CC7 are between the positions of the corresponding word lines WL0 to WL7 and the insulating film 34 located immediately above the word lines. For example, a lower end of the conductor 44 of the word line contact CC0 is located at the corresponding word line WL0. A lower end of the stacked film 40 of the word line contact CC0 is located between the position of the corresponding word line WL0 and the insulating film 34 located immediately above the word line. For example, a lower end of the conductor 44 of the word line contact CC3 is located at the corresponding word line WL3. A lower end of the stacked film 40 of the word line contact CC3 is located between the position of the corresponding word line WL3 and the insulating film 34 located immediately above the word line. Thereby, the conductors 44 of the word line contacts CC0 to CC7 are electrically connected to the corresponding word lines WL0 to WL7, respectively, and are electrically isolated from the other word lines. The number of word line contacts CCk (k=0 to 7) is the same as the number of word lines WLk.

The word line contacts CC0 to CC7 penetrate other word lines to reach their respective word lines WL0 TO WL7. For example, the word line contact CC0 penetrates other word lines WL1 to WL7 in the Z direction in order to connect to the corresponding word line WL0. The conductor 44 of the word line contact CC0 is electrically isolated from the word lines WL1 to WL7 due to the stacked film 40. The word line contact CC3 penetrates other word lines WL4 to WL7 located above the word line WL3 in the Z direction in order to connect to the corresponding word line WL3. The conductor 44 of the word line contact CC3 is electrically isolated from the word lines WL4 to WL7 due to the stacked film 40.

The support portion HR is provided between the word line contacts CC0 to CC7 in a region where the word line contacts CC0 to CC7 are provided. The support portion HR is provided as a columnar body that extends the stacked body S1 in the Z direction and penetrates the stacked body S1. The support portion HR functions as a support that curbs collapse of the stacked body S1 (memory cell array MCA1) in a replacement process to be described later. Thus, the support portions HR are disposed at intervals that are equal to or smaller than intervals at which collapse can be curbed. The support portion HR has a columnar shape and extends in the Z direction from an insulator 36 to reach the source layer SL1.

For example, an insulating material such as a silicon oxide film is used for the support portion HR. Thus, the word line contacts CC0 to CC7 may come into contact with a portion of the support portion HR as long as their tips are connected to the word lines WL0 to WL7, respectively.

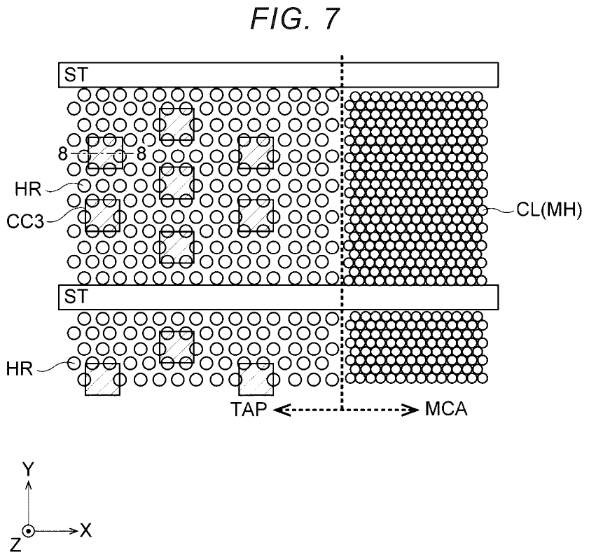

FIG. 7 is a plan view showing configuration examples of the memory cell array MCA, the word line contact CC3, and the support portion HR. The support portions HR are provided at any positions on the stacked body S1 at intervals of a predetermined value or less. In a plan view from the Z direction, the support portion HR is disposed around the word line contact CC3, and is disposed, for example, at the apex of a hexagon. The word line contact CC3 is provided between six support portions HR adjacent to each other.

The word line contact CC3 is provided in a connection region TAP but is not provided in a region where the memory cell array MCA is formed.

In a plan view from the Z direction, the word line contact CC3 may have a substantially rectangular shape, a substantially circular shape, or a substantially elliptical shape.

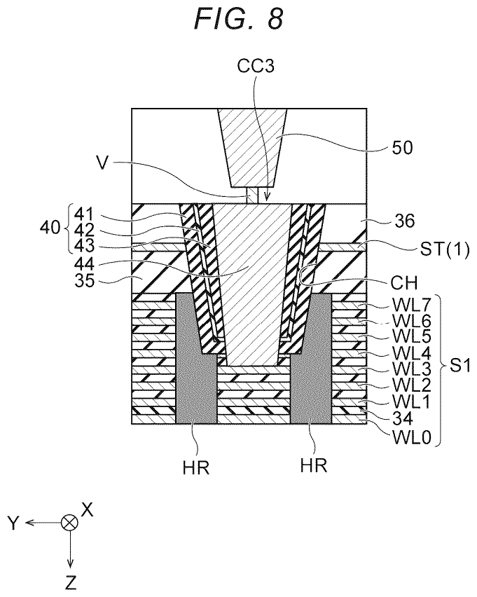

In a plan view from the Z direction, an upper end of the word line contact CC3 may overlap the support portion HR, as shown in FIG. 7. However, as shown in FIG. 8, it is preferable that a lower end of the word line contact CC3 does not overlap the support portion HR so as not to be short-circuited to the word line WL. The planar configurations of the other word line contacts CC0 to CC2 and CC4 to CC7 may be the same as the planar configuration of the word line contact CC3.

In the region where the memory cell array MCA is formed, a plurality of columnar bodies CL (memory holes MH) are disposed more densely than the support portions HR. Each of the plurality of columnar bodies CL has a diameter smaller than that of the support portion RH.

FIG. 8 is a cross-sectional view showing a configuration example of the word line contact CC3. FIG. 8 shows a cross-section taken along line 8-8 in FIG. 7. Each of the word line contacts CC0 to CC2 and CC4 to CC7 has the same configuration as that of the word line contact CC3, although they have different depths (although they connect different word lines). Thus, a configuration of the word line contact CC3 will be described, and the description of the word line contacts CC0 to CC2 and CC4 to CC7 will be omitted.

The word line contact CC3 is provided between the support portions HR adjacent to each other, and extends in the Z direction in the stacked body S1. The word line contact CC3 includes the stacked film 40 including a plurality of insulating films 41 to 43 stacked on the inner wall of the contact hole CH, and a conductor 44 buried in the stacked film 40 in the contact hole CH. The conductor 44 extends in the Z direction in the stacked body S1, is provided to correspond to the word line WL3, and is connected to the word line WL3. The stacked film 40 is a spacer film that is provided up to immediately above the word line WL3 and covers the outer periphery of the conductor 44. The stacked film 40 includes the insulating films 41 to 43 stacked between the conductor 44 and the stacked body S1. Thereby, the conductor 44 is electrically connected to the word line WL3 while being electrically insulated from the word lines WL4 to WL7 and the gate of the select transistor ST(1). The conductor 44 is connected to a wiring 50 via a via V, and applies a word voltage to the word line WL3 via the wiring 50.

For example, a silicon oxide film (SiO₂) is used for the insulating films 41 and 43. The film thicknesses of the insulating films 41 and 43 are, for example, approximately 50 nm. For example, a silicon nitride film (Si₃N₄) and/or an aluminum oxide film (AlO₃) is used for an insulating film 42 between the insulating film 41 and the insulating film 43. The film thickness of the insulating film 42 is, for example, 10 nm to 20 nm. In this manner, the stacked film 40 is configured with the stacked films of the insulating films 41 to 43, and thus it is possible to curb over-etching of the word line and reliably connect the conductor 44 to the corresponding word line at the time of forming the word line contact, as will be described later.

The stacked film 40 may be a three-layer film including the plurality of insulating films 41 to 43 (ONO films). However, the stacked film 40 may be a stacked film of four or more layers in which a plurality of insulating films are provided between the insulating film 41 and the insulating film 43.

The wiring 50 is provided on the word line contact CC3. The wiring 50 is connected to any one circuit in the control circuit layer 130 in FIG. 3 and is used to apply a word voltage to the word line WL3 in a read operation or a write operation.

Next, a method of manufacturing the semiconductor memory device 1 will be described.

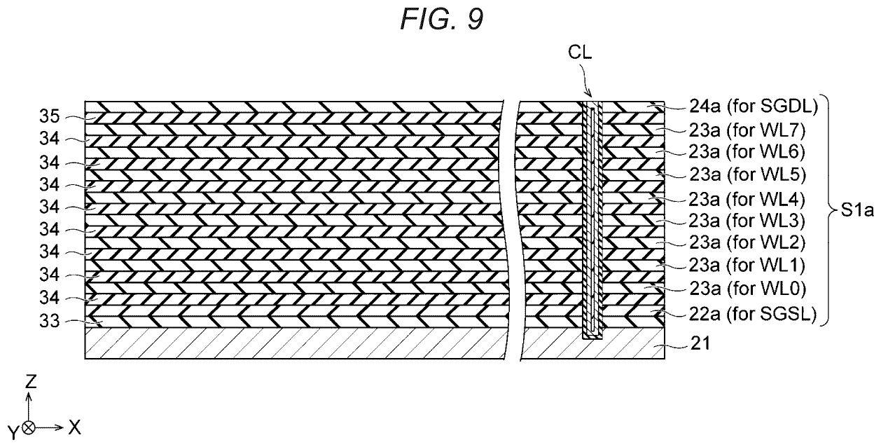

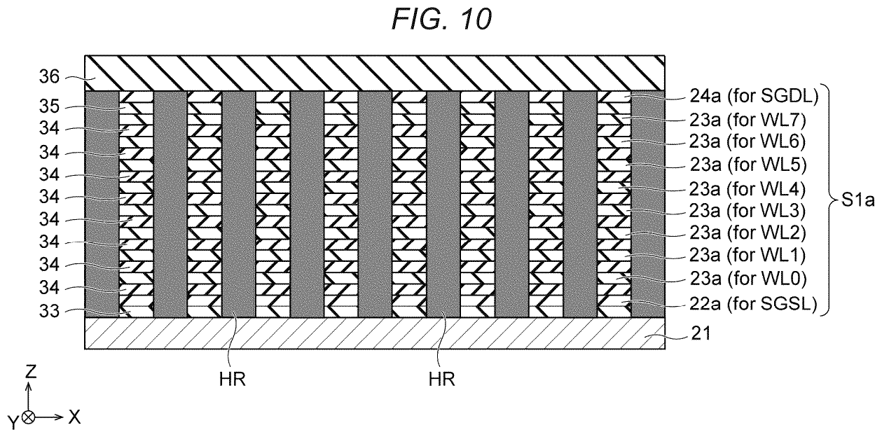

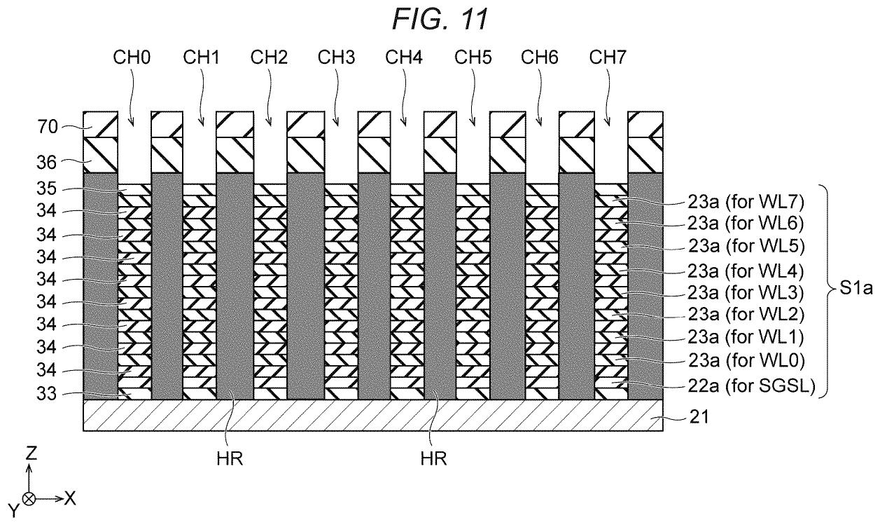

FIGS. 9 to 20 are cross-sectional views showing an example of a method of manufacturing the semiconductor memory device 1 according to the first embodiment. FIGS. 9 to 20 show the region of the word line contact CC in the stacked body S1.

First, as shown in FIG. 9, a stacked body S1a is formed on a conductor 21, the stacked body S1a being configured such that sacrificial films 22a to 24a and insulating films 33 to 35 are alternately stacked in a z-axis direction. The conductor 21 functions as the source layer SL1. For the conductor 21, for example, a conductive material such as doped polysilicon is used. For example, a silicon oxide film is used for the insulating films 33 to 35, and for example, a silicon nitride film is used for the sacrificial films 22a to 24a. A substrate, which is not shown in the drawing, is provided below the conductor 21.

Next, columnar bodies CL extending in the Z direction in the stacked body Sla are formed. The columnar body CL is formed by forming a memory hole reaching the conductor 21 and depositing the cover insulating film 38, the charge trapping film 37, the tunnel insulating film 236, the semiconductor body 25, and the core layer 26 inside the memory hole. The columnar body CL is not shown in FIG. 10 and the subsequent drawings.

Next, a hole is formed in a region where the support portion HR is formed by using lithography technology and etching technology. The hole is formed to extend in the Z direction in the stacked body S1a and to penetrate the stacked body S1a. By filling this hole with an insulating material such as a silicon oxide film, the support portion HR is formed as shown in FIG. 10. The insulator 36 is formed on the stacked body S1a and the support portion HR.

Next, a material of a hard mask 70 is formed on the insulator 36. For example, a silicon nitride film is used as the material of the hard mask 70. Next, processing is performed to remove the material of the hard mask 70 in a region where the word line contact CC is formed by using lithography technology and etching technology.

Next, the insulator 36 and the sacrificial film 24a are processed by a reactive ion etching (RIE) method or the like by using the hard mask 70 as a mask. Thereby, contact holes CH0 to CH7 are formed in the region where the word line contact CC is formed.

In order to make the depths of the contact holes CH0 to CH7 different from each other, lithography technology and etching technology are repeatedly performed.

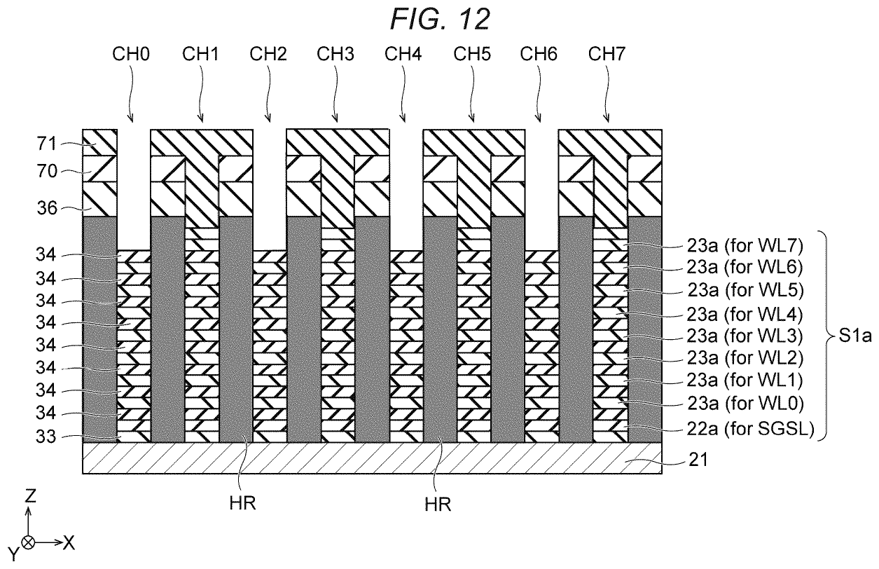

For example, every other contact hole of the contact holes CH0 to CH7 is filled with a resist film 71 by using lithography technology. The uppermost layers of the insulators 35 and sacrificial films 23a are processed using the resist film 71 as a mask. Thereby, a structure shown in FIG. 12 is obtained.

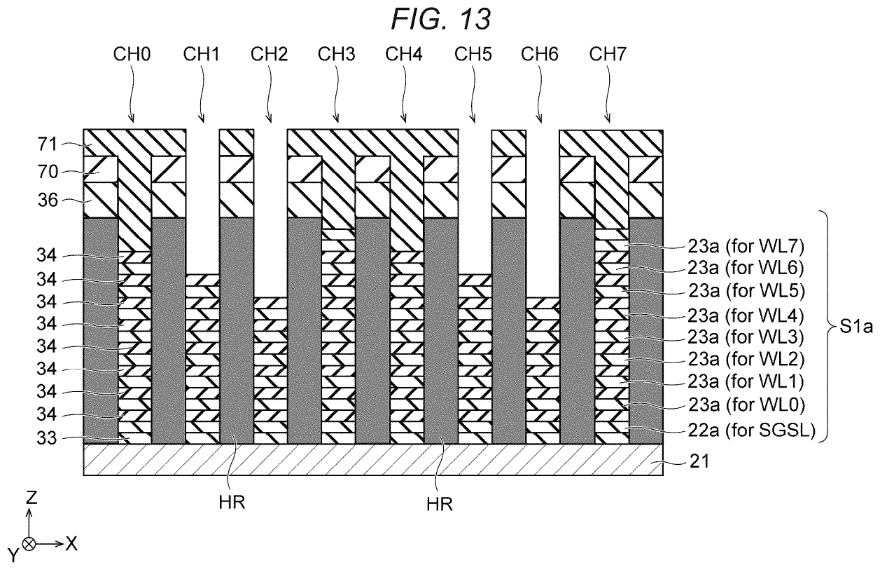

Next, every second contact hole of the contact holes CH0 to CH7 is filled with the resist film 71 by using lithography technology. The layers of the insulators 34 and the sacrificial films 23a are processed one by one using the resist film 71 as a mask. Thereby, a structure shown in FIG. 13 is obtained.

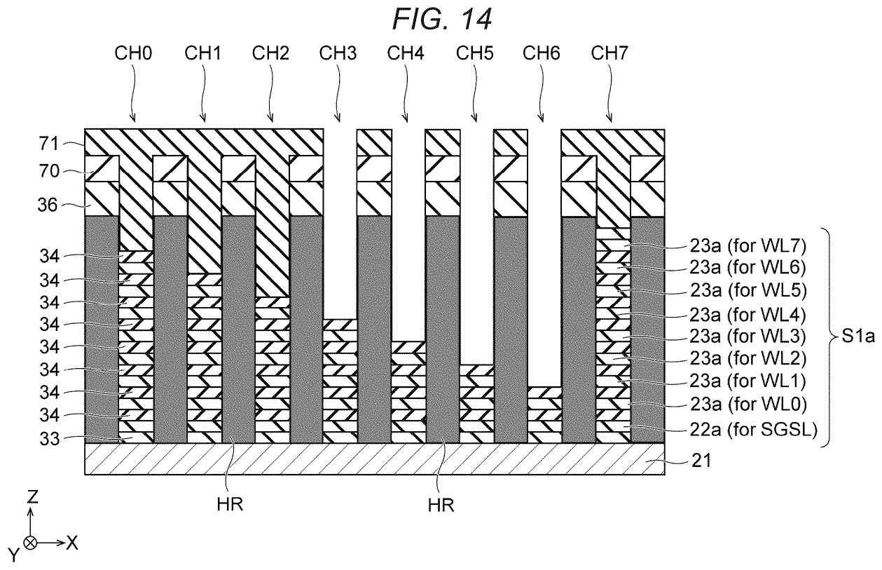

Next, every third contact hole of the contact holes CH0 to CH7 is filled with the resist film 71 by using lithography technology. The layers of the insulators 34 and the sacrificial films 23a are further processed one by one using the resist film 71 as a mask. Thereby, a structure shown in FIG. 14 is obtained.

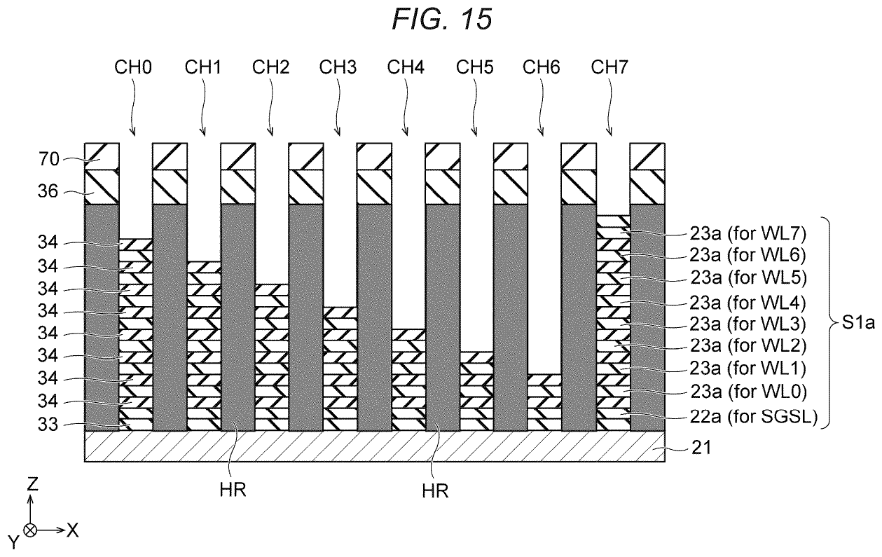

When the resist film 71 is removed, the contact holes CH0 to CH7 having different depths are formed in the stacked body S1a as shown in FIG. 15. The contact holes CH0 to CH7 extend in the Z direction in the stacked body S1a and reach their corresponding insulating films 34. At the bottoms of the contact holes CH0 to CH7, the insulating film 34 respectively located immediately above the sacrificial films 23a having the corresponding heights is exposed. The number of contact holes is not particularly limited.

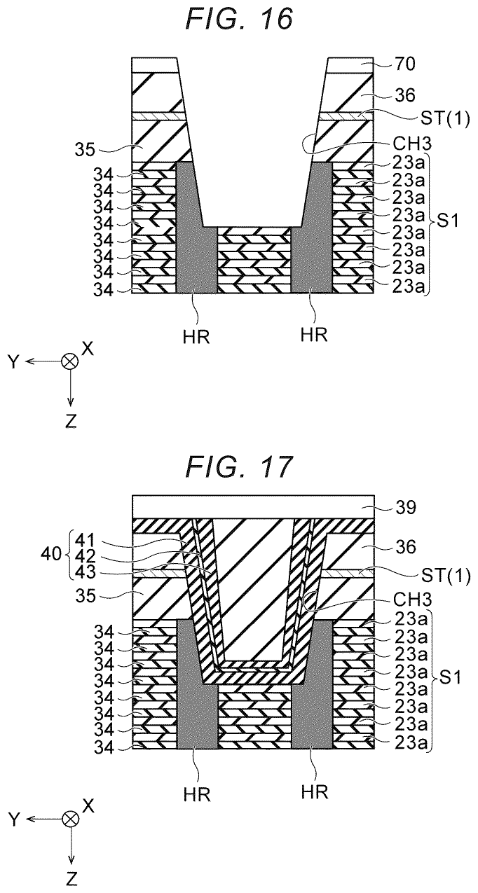

A process of forming the word line contact CC3 will be further described focusing on the contact hole CH3 with reference to FIGS. 16 to 20. The word line contacts CC0 to CC2 and CC4 to CC7 are formed in the same manner as the word line contact CC3, and thus the description of a process of forming the word line contacts CC0 to CC2 and CC4 to CC7 will be omitted.

As shown in FIG. 16, after the contact hole CH3 is formed, the insulating film 41 is formed on the inner wall of the contact hole CH3. For example, a silicon oxide film is used for the insulating film 41. Next, the insulating film 42 is formed on the insulating film 41 on the inner wall of the contact hole CH3. For example, a silicon nitride film or an aluminum oxide film is used for the insulating film 42. Next, an insulating film 43 is formed on the insulating film 42 on the inner wall of the contact hole CH3. For example, a silicon oxide film is used for the insulating film 43. Next, a sacrificial film 44a is buried in the insulating film 43 in the contact hole CH3. For example, a polysilicon film is used for the sacrificial film 44a.

Next, the insulating films 41 and 42 and the sacrificial film 44a are polished and planarized using a chemical mechanical polishing (CMP) method or the like. Next, an insulating film 39 is formed on the insulating films 41 and 42 and the sacrificial film 44a. Thereby, a structure shown in FIG. 17 is obtained.

Next, as shown in FIG. 18, the sacrificial film 23a is replaced with the electrode film 23 (replacement step). At this time, the gate of the select transistor ST(1) is also replaced with the same material as that of the electrode film 23. Thereby, the word lines WL0 to WL7 are formed. Furthermore, the gate of the select transistor ST(1) is also formed. In this replacement process, the support portion HR supports the insulating film 34 when the sacrificial film 23a is removed. Thereby, even when a cavity is formed between the insulating films 34 due to the removal of the sacrificial film 23a, the insulating film 34 is not depressed because the support portion HR supports the insulating film 34.

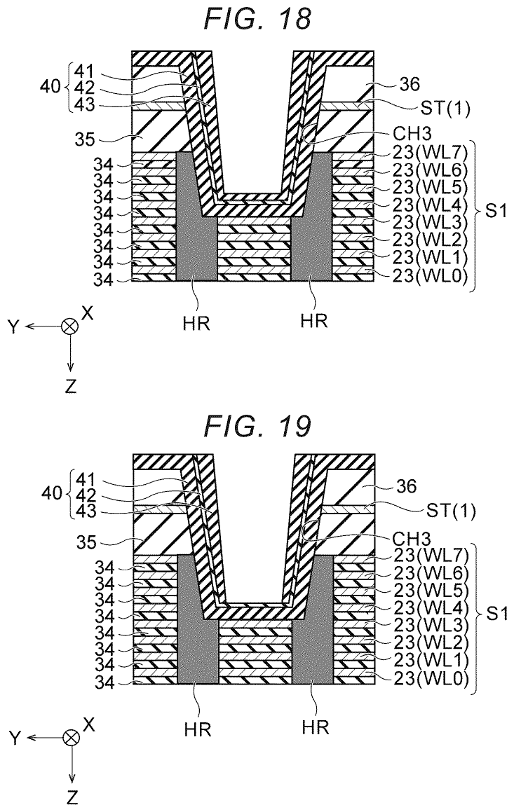

Next, the insulating film 39 and the sacrificial film 44a are removed. Furthermore, the bottom of the contact hole CH3 is etched back anisotropically using etching technology such as an RIE method. Thereby, as shown in FIG. 19, the insulating film 43 (for example, a silicon oxide film) at the bottom of the contact hole CH3 is removed, and the insulating film 42 (for example, a silicon nitride film) is exposed. At this time, since the insulating film 42 is formed of a silicon nitride film that is resistant to etching of a silicon oxide film, the insulating film 42 can function as an etching stopper.

Next, the bottom of the contact hole CH3 is etched back anisotropically using etching technology such as an RIE method. Thereby, the insulating film 42 (for example, a silicon nitride film) at the bottom of the contact hole CH3 is removed, and the insulating film 41 (for example, a silicon oxide film) is exposed. At this time, since the insulating film 41 is formed of a silicon oxide film that is resistant to etching of a silicon nitride film, the insulating film 41 can function as an etching stopper.

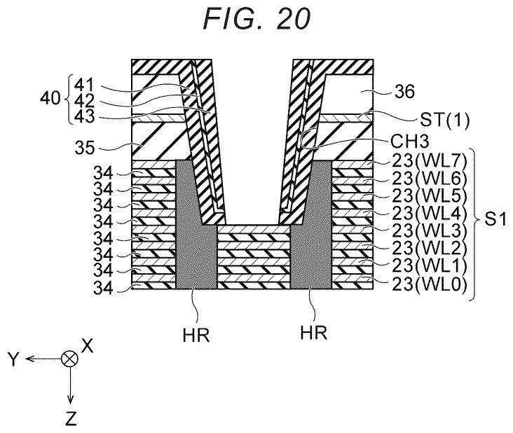

Furthermore, the bottom of the contact hole CH3 is etched back anisotropically using etching technology such as an RIE method. Thereby, as shown in FIG. 20, the insulating film 43 (for example, silicon oxide) and the insulating film 34 at the bottom of the contact hole CH3 are removed, and the electrode film 23 (for example, tungsten) is exposed.

Here, the stacked film 40 in which the insulating films 41 to 43 are stacked is provided at the bottoms of the contact holes CH0 to CH7. The insulating film 42 is formed of a material having an etching selectivity different from those of the insulating films 41 and 43, and functions as an etching stopper for the insulating film 43. Thus, even when the contact holes CH0 to CH7 have different depths, the insulating films 43 can be equally removed from the bottoms of the contact holes CH0 to CH7. Further, the insulating film 41 functions as an etching stopper for the insulating film 42. Thus, even when the contact holes CH0 to CH7 have different depths, the insulating films 42 can be equally removed from the bottoms of the contact holes CH0 to CH7. Thus, etching for exposing the electrode films 23 (the word lines WL0 to WL7) at the bottoms of the contact holes CH0 to CH7 is only required to remove the insulating film 41 and the insulating film 34.

Thereafter, as shown in FIG. 8, the conductor 44 is buried in the stacked film 40 in the contact hole CH3. Thereby, the word line contact CC3 connected to the word line WL3 is formed. The word line contacts CC0 to CC2 and CC4 to CC7 may also be formed in the same manner as the word line contact CC3. Further, the wiring 50 is formed on the conductor 44. Thereafter, the memory cell array MCA1 according to the present embodiment is completed by forming an interlayer insulating film and a multilayer wiring layer.

If a single layer film is used instead of the stacked film 40, it is necessary to simultaneously etch the relatively thick insulating films at the bottoms of the contact holes CH0 to CH7 at the same time. The contact holes CH0 to CH7 have different depths. Thus, when the relatively thick insulating films at the bottoms of the contact holes CH0 to CH7 are etched at the same time, the insulating films may remain at the bottoms of the contact holes CH0 to CH7 due to under-etching, and conversely, the electrode films 23 are cut at the bottoms of the contact holes CH0 to CH7 due to excessive over-etching. This may result in a concern that the word line contacts CC0 to CC7 may not be connected to the intended word lines WL0 to WL7 or may be short-circuited to the unintended word lines WL0 to WL7.

Meanwhile, according to the present embodiment, the stacked film 40 in which the insulating films 41 to 43 are stacked is provided at the bottoms of the contact holes CH0 to CH7. The insulating film 42 functions as an etching stopper for the insulating film 43. Thus, even when the contact holes CH0 to CH7 have different depths, the insulating films 43 can be equally removed from the bottoms of the contact holes CH0 to CH7 without excessive over-etching. Further, the insulating film 41 functions as an etching stopper for the insulating film 42. Thus, even when the contact holes CH0 to CH7 have different depths, the insulating films 42 can be equally removed from the bottoms of the contact holes CH0 to CH7 without excessive over-etching. Thus, etching for exposing the electrode films 23 (the word lines WL0 to WL7) at the bottoms of the contact holes CH0 to CH7 is only required to remove the relatively thin insulating films 41 and insulating films 34. Thereby, even when the contact holes CH0 to CH7 have different depths, it is possible to curb excessive over-etching and expose the intended word lines WL0 to WL7. As a result, in the present embodiment, the word line contacts CC0 to CC7 can be reliably connected to the intended word lines WL0 to WL7, respectively.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a first stacked body that includes a plurality of first insulating films and a plurality of first conductive films alternately stacked in a first direction;
a plurality of first columnar bodies that each include a first semiconductor structure extending through the first stacked body in the first direction, and a first insulator structure provided between the first semiconductor structure and the first stacked body, the plurality of first columnar bodies being configured such that memory cells are provided to correspond to intersections between the first columnar bodies and the first stacked body; and
a plurality of second columnar bodies that each include at least one conductor extending through the first stacked body in the first direction, and are each coupled to a corresponding one of the first conductive films and a stacked film including second, third, and fourth insulating films, wherein the second to fourth insulating films are provided between the at least one conductor and the first stacked body.

2. The semiconductor memory device according to claim 1, wherein
the second and fourth insulating films each include a silicon oxide film, and
the third insulating film includes a silicon nitride film or an aluminum oxide film.

3. The semiconductor memory device according to claim 1, further comprising:
a plurality of third columnar bodies each extending through the first stacked body in the first direction, disposed around the second columnar body, and including an insulating material.

4. The semiconductor memory device according to claim 1, wherein a depth of the conductor of each of the plurality of second columnar bodies is vertically aligned with a position of the corresponding first conductive film.

5. The semiconductor memory device according to claim 1, wherein a depth of the stacked film of each of the plurality of second columnar bodies is located between a position of the corresponding first conductive film and a corresponding one of the first insulating films located immediately above the first conductive film.

6. The semiconductor memory device according to claim 1, wherein the stacked film includes four or more layers in which a plurality of insulating films are provided between the second and fourth insulating films.

7. The semiconductor memory device according to claim 1, wherein the plurality of second columnar bodies each penetrate through one or more other first conductive films different from the corresponding first conductive film.

8. A method of manufacturing a semiconductor memory device, the method comprising:
forming a first stacked body including a plurality of first insulating films and a plurality of first sacrificial films alternately stacked in a first direction;
forming a first columnar body including a first semiconductor structure extending in the first direction in the first stacked body, and a first insulator structure provided between the first semiconductor structure and the first stacked body;
forming a contact hole extending through the first stacked body in the first direction to reach a corresponding one of the plurality of first insulating films;
forming a stacked film including second, third, and fourth insulating films around inner walls of the contact hole;
removing a portion of the fourth insulating film at a bottom of the contact hole with the third insulating film serving as a stopper;
removing the third insulating film at the bottom of the contact hole with the second insulating film serving as a stopper;
removing the second insulating film and the first insulating film at the bottom of the contact hole to expose a corresponding one of the first conductive films located immediately under the corresponding first insulating film; and
filling the contact hole with a conductor to form a contact connected to the corresponding first conductive film.

9. The method according to claim 8, wherein
the second and fourth insulating films each include a silicon oxide film, and
the third insulating film includes a silicon nitride film or an aluminum oxide film.

10. A semiconductor memory device comprising:
a first stacked body that includes a plurality of first insulating films and a plurality of first conductive films alternately stacked in a first direction;
a plurality of first columnar bodies that each include a first semiconductor structure extending through the first stacked body in the first direction, and a first insulator structure provided between the first semiconductor structure and the first stacked body, the plurality of first columnar bodies being configured such that memory cells are provided to correspond to intersections between the first columnar bodies and the first stacked body; and
a plurality of second columnar bodies that each include at least one conductor extending through the first stacked body in the first direction, wherein the at least one conductor has a bottom surface coupled to a corresponding one of the first conductive films and an upper sidewall coupled to a stacked film including second, third, and fourth insulating films.

11. The semiconductor memory device according to claim 10, wherein the second to fourth insulating films are provided between the at least one conductor and the first stacked body.

12. The semiconductor memory device according to claim 10, wherein
the second and fourth insulating films each include a silicon oxide film, and
the third insulating film includes a silicon nitride film or an aluminum oxide film.

13. The semiconductor memory device according to claim 10, wherein a depth of the at least one conductor is vertically aligned with a position of the corresponding first conductive film.

14. The semiconductor memory device according to claim 10, wherein the stacked film includes four or more layers in which a plurality of insulating films are provided between the second and fourth insulating films.

15. The semiconductor memory device according to claim 10, wherein the plurality of second columnar bodies each penetrate through one or more other first conductive films different from the corresponding first conductive film.
